(19) United States
(12) Patent Application Publication
(10) Pub. No.: US 2009/0229649 A1
(43) Pub. Date: Sep. 17, 2009

(54) THERMAL MANAGEMENT FOR IMPROVED ENGINE OPERATION

(75) Inventors: Jihui Yang, Lakeshore (CA); Michael G. Reynolds, Troy, MI (US); Francis R. Stabler, Troy, MI (US)

Correspondence Address: General Motors Corporation;c/o REISING, ETHINGTON, BARNES, KISSELLE, P.C., P.O. BOX 4390, TROY, MI, 48099-4390, US

(73) Assignee: GM GLOBAL TECHNOLOGY OPERATIONS, INC., DETROIT, MI (US)

(21) Appl. No.: 12/396,894

(22) Filed: Mar. 3, 2009

Related U.S. Application Data
(60) Provisional application No. 61/036,679, filed on Mar. 14, 2008.

(51) Int. Cl. H01L 35/34; F01P 7/14; H01L 35/00

(52) U.S. Cl. 136/201; 123/41.08; 136/200

(57) ABSTRACT

A method comprising flowing engine combustion exhaust through a thermoelectric device and flowing engine coolant through the thermoelectric device to provide faster engine and transmission warming (coolant, oil).

This is application claims the benefit of U.S. Provisional Application Ser. No. 61/036,679 filed Mar. 14, 2008.

One or more inventions set forth herein was made under Government Contract No. DE-FC27-04NT42278. The government may have certain rights in one or more inventions described herein.

### TECHNICAL FIELD

The field to which the disclosure generally relates includes thermal management of engine operations and vehicle systems including thermal management components.

### BACKGROUND

It has been discovered that an engine operates with better efficiency and lower emissions if the engine, coolant, oil, and transmission fluid temperatures each are in an optimum range. Engine coolant heat is typically used to warm the engine oil and transmission fluid and these methods are not covered in this embodiment.

### SUMMARY OF EXEMPLARY EMBODIMENTS OF THE INVENTION

One exemplary embodiment may include a method comprising flowing engine combustion exhaust through a thermoelectric device and flowing engine coolant through the thermoelectric device.

Another exemplary embodiment may include a system comprising an engine plumbed to flow combustion exhaust from the engine through a thermoelectric device, and the engine plumbed to flow coolant through the thermoelectric device.

Another exemplary embodiment may include a method comprising starting up a combustion engine, determining whether coolant flowing through the combustion engine is above a minimum threshold, and if not, flowing engine coolant from the engine to a thermoelectric device so that heat is exchanged from exhaust gas from the engine flowing through the thermoelectric device to the coolant flowing through the thermoelectric device, and if the coolant flowing through the engine is above a minimum temperature threshold, stopping the flow of coolant through the thermoelectric device and flowing the coolant through a radiator to cool the coolant.

Another exemplary embodiment may include a method comprising determining if an engine coolant in a vehicle is below an optimum temperature, and if so, routing the coolant from the engine to the cold side of a thermoelectric generator connected to the exhaust system of the engine to exchange heat from the exhaust gases in the exhaust system to heat the engine coolant, and thereafter returning the coolant to the engine to warm the engine.

Other exemplary embodiments of the invention will become apparent from the detailed description provided hereinafter. It should be understood that the detailed description and specific examples, while disclosing exemplary embodiments of the invention, are intended for purposes of illustration only and are not intended to limit the scope of the invention.

### BRIEF DESCRIPTION OF THE DRAWINGS

Exemplary embodiments of the invention will become more fully understood from the detailed description and the accompanying drawings, wherein:

FIG. 1 illustrates a vehicle system including a thermoelectric device connected to the exhaust system of a combustion engine according to one exemplary embodiment.

FIG. 2 is a schematic diagram of a vehicle system for thermal management of engine coolant according to one exemplary embodiment.

FIG. 3 is a flowchart illustrating a method of controlling the flow of engine coolant in a vehicle according to one exemplary embodiment.

FIG. 4 is a schematic illustration of a system for controlling the flow of engine coolant according to another exemplary embodiment of the invention.

FIG. 5 is a schematic illustration of a thermoelectric device operating as an electrical generator according to one exemplary embodiment.

### DETAILED DESCRIPTION OF EXEMPLARY EMBODIMENTS

The following description of the embodiment(s) is merely exemplary (illustrative) in nature and is in no way intended to limit the invention, its application, or uses.

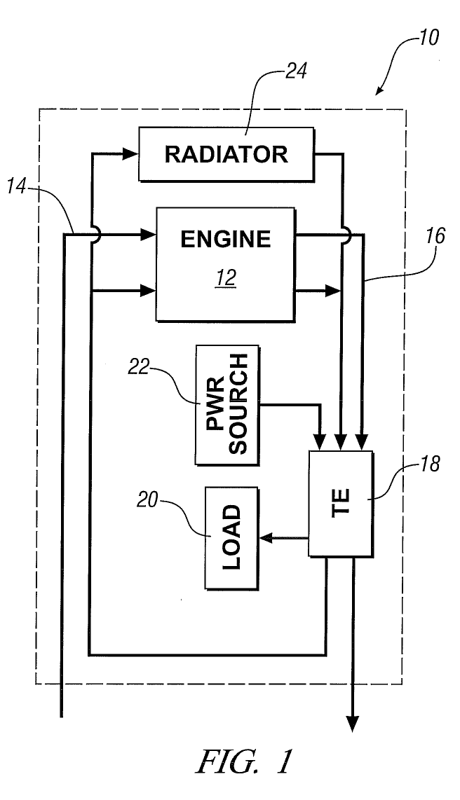

Referring now to FIG. 1, one exemplary embodiment includes a vehicle 10 having an engine 12 and an engine breathing system including an air intake conduit 14 connected to the engine and an exhaust conduit 16 connected to the engine and having an open end to discharge combustion gases to the atmosphere after treatment. The vehicle may also include a thermoelectric device 18, which may be connected to the exhaust conduit 16. The thermoelectric device 18 may also be plumbed to a radiator 24 and the engine 12 to flow coolant or cooling fluid selectively to and from the engine 12 and radiator 24. The thermoelectric device 18 may be constructed and arranged to function as a generator to produce electricity to be used by a load 20, which may include but is not limited to vehicle lights, fans, pumps, energy storage device, such as, but not limited to, a battery and/or propulsion motor(s) in the case of a hybrid vehicle. The vehicle 10 may also include a power source 22 such as a battery to supply a current to the thermoelectric device 18 allowing the same to be utilized as a heat pump.

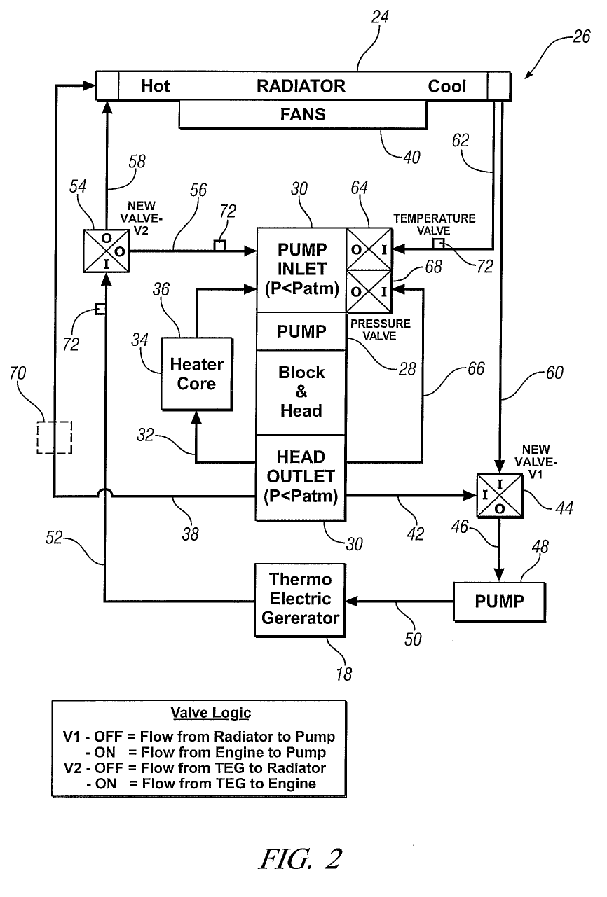

Referring now to FIG. 2, one exemplary embodiment of the invention includes a system including an engine 12 and a first pump 28 connected to the engine 12 to flow coolant through the engine 12 to cool the same. The pump 28 may have a pump inlet 30 associated therewith. A head outlet 33 may be connected to the engine 12 and constructed and arranged to deliver coolant through line 32 to a heater core 34, which may be used to heat the passenger compartment of the vehicle 10. Coolant line 36 may be provided from the heater core 34 to the pump inlet 30. Coolant may also flow through line 38 to the hot side of the radiator 24 and through the radiator 24 where at least one fan 40 is positioned to cool the cooling fluid traveling through the radiator. Cooling fluid may also flow from the head outlet 33 through line 42 to a first valve 44. If the first valve 44 is open, coolant may flow through the first valve 44 and through line 46 into a second pump 48. Coolant may flow from the second pump 48 through line 50 to a thermoelectric device 18, which may be a generator. The coolant may flow over the cold side of the thermoelectric device 18 acting as a heat sink for heat transferred from the exhaust conduit 16 to warm the coolant. The warm coolant may flow through line 52, through a second valve 54 and either through line 56 back into the engine 12 by way of the pump inlet 30 and pump 28, or through line 58 into the radiator 24. Coolant exiting the radiator 24 may travel through line 60 to the first valve 44 and/or through line 62 into the engine 12 by way of a third valve 64, and the pump inlet 30 and pump 12. Coolant may also flow from the header outlet 33 through line 66 and into the engine 12 by way of a fourth valve 68, pump inlet 30 and pump 28.

Optionally a fifth valve 70 may be provided in line 38 to prevent coolant from flowing from the engine 12 back to the radiator 24 as desired. Temperature sensors 72 may be provided throughout the system 26 including, but not limited to, in lines 62, 56 and/or 52 to determine whether the coolant is within an optimum temperature range associated with an optimum operating temperature range for the engine 12, engine oil, and transmission oil, or determine if the coolant is above a minimum threshold temperature as desired.

Upon engine startup, coolant flows from the radiator 24 through line 62 and into the engine block 12. A sensor, for example sensor 72 in line 62 may be utilized to determine whether the coolant is within a predetermined optimum temperature range or above a minimum threshold temperature. If the coolant is within an optimum temperature range or above a minimum threshold, the third valve 64 remains open and the first valve 44 is positioned to allow coolant to flow from the radiator through the second pump 48 and the thermoelectric device 18. However, if the temperature of the coolant is outside of an optimum temperature range or below a minimum temperature threshold, the third valve 64 may be closed to prevent cold coolant from flowing into the engine. The first valve 44 may be positioned (opened) to allow coolant to flow from the engine through the second pump 48 and across the cold side of the thermoelectric device 18 so that heat is transferred from the engine exhaust to the coolant by way of the thermoelectric device. The warmed coolant then exits the thermoelectric device 18 and flows through line 52 and through the second valve 54, which may be positioned (opened) to allow coolant to flow through line 56 back into the engine 12 to heat up the engine. If the fifth valve 70 is present, the fifth valve 70 may be closed to prevent coolant from flowing from the header outlet 33 back into the radiator 24. The fourth valve 68 may be opened, closed, or partially opened to control the amount of coolant flowing from the header outlet 33 back into the engine block 12 and/or through line 42 into the first valve 44 and then back through the second pump 48 and the thermoelectric device 18 to be further heated by the exhaust gases. The sensor 72 in line 56 or at another appropriate location may be monitored to determine when the coolant temperature has reached an optimum temperature range for operation of the engine or when the coolant is above a minimum threshold value. If the coolant reaches a minimum threshold value or is within an optimum temperature range, the first valve 44 may be positioned to allow coolant from the radiator to flow through line 46 to the pump 48, and the fifth valve 70, if present, may be opened to cause the coolant to travel through line 38 back into the radiator 24 to be cooled as desired. The third valve 64 may be opened to allow the coolant exiting the cool side of the radiator 24 to return to the engine block 12. The fourth valve 64 may be closed, opened or partially opened as desired.

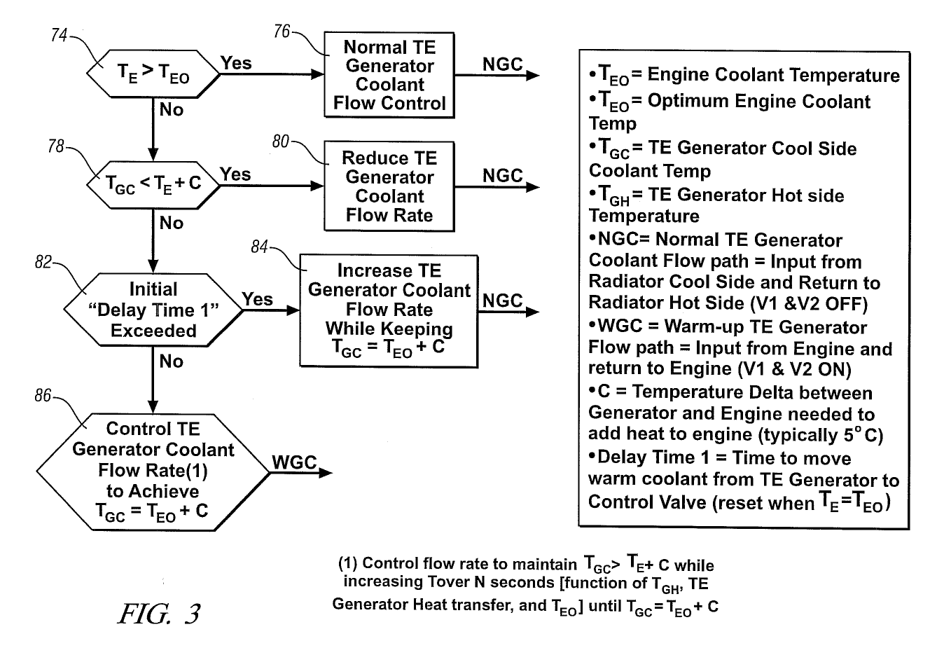

FIG. 3 is a flowchart illustrating a method according to one exemplary embodiment. As illustrated in FIG. 3, a determination may be made as to whether the engine coolant temperature T_{E} is greater than or equal to an optimum engine coolant temperature T_{EO} at step 76. If yes, the thermoelectric generator 18 is operated using a traditional coolant flow path wherein the coolant flows from the radiator, into the engine and then back into the radiator 24 and so that the first valve 44 and second valve 54 in FIG. 2 are closed (ie., positioned to allow coolant to flow from the radiator through pump 48 to the thermoelectric generator 18 and back to the radiator through valve 54). However, if T_{E} is not greater than or equal to T_{EO}, a determination is made as to whether the thermoelectric generator 18 cold side coolant temperature is less than T_{E}, engine coolant temperature plus a temperature delta, which may typically be 5° C., step 78. If yes, control the coolant flow rate with pump 48 such that the coolant has more time to be heated by exhaust heat through the thermoelectric generator 18, (alternately, variable flow valves may be used and controlled to reduce the coolant flow rate through the thermoelectric generator 18), step 80. This increase in T_{GC} results in a reduced efficiency of the thermoelectric generator during warm-up, but increases the efficiency of the total system by warming the engine faster. If no, a determination may be made as to whether an initial delay time has been exceeded, step 82. The use of a delay time determination is optional. The delay time may be utilized to avoid pumping a relatively small amount of cold coolant contained in line 52 into the engine 12 while the thermoelectric generator 18 is still warming up. The coolant in line 52 will initially contain cold (ambient temperature) coolant. A delay time for opening the first and second valves 44 and 54 allows for a small volume of coolant to flow into the radiator 24 instead of the engine 12. Then when warm coolant arrives at the second valve 54, as may be determined by 1) sensor 72 in line 52 or 2) a computed time delay based on pump 48 flow rate and line 52 volume, the second valve 54 may be operated to allow coolant to flow through line 56 into pump inlet 30. If the initial delay time has not been exceeded, the thermoelectric generator coolant flow rate is increased while keeping T_{GC} greater than T_{E} plus a temperature delta as shown in step 84. If the initial delay time has been exceeded, the thermoelectric generator coolant flow rate is controlled to achieve T_{GC} equal to T_{EO} plus a temperature delta as indicated in step 86. This flow is maintained until T_{E} is equal to or greater then T_{EO}, then Valves 44 and 54 are again positioned to flow coolant from the radiator, through the Pump 48 and the thermoelectric generator and returned to the radiator.

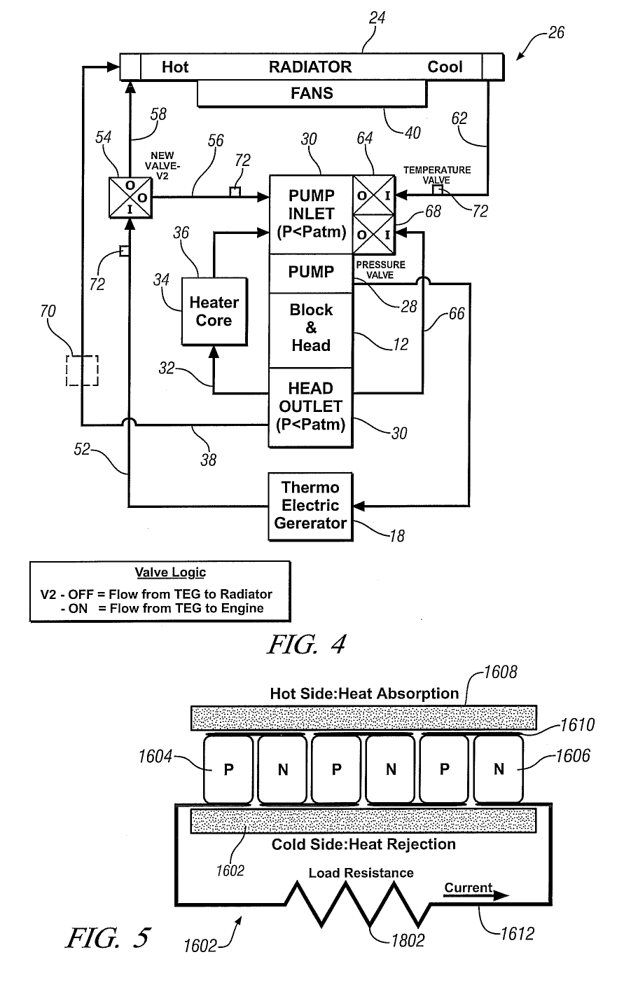

FIG. 4 illustrates another exemplary embodiment of the invention. The system 26 illustrated in FIG. 4 is similar to the system of FIG. 3. However, in FIG. 4, lines 60, 42, the first valve 44, line 46, the second pump 48, and line 50 may be eliminated. This embodiment has the effect of reducing the efficiency of the thermoelectric generator because it increases the temperature of coolant on the cold side of the generator but it does reduce the cost and complexity of the system. Alternatively, line 90 may be provided from the first pump 28 to the thermoelectric device 18. The second pump 48 may be a variable flow pump to vary the amount of coolant flowing through the thermoelectric device 18 in both designs of FIGS. 3-4.

The system illustrated in FIG. 4 may be utilized to warm up the engine 12 at startup by flowing engine coolant through the thermoelectric generator 18 to exchange heat with the exhaust gas and flow the warmed coolant through the second valve 54 back into the engine 12. When the coolant has reached a predetermined minimum threshold, the second valve 54 may be adjusted to allow the coolant to flow through line 58 into the hot side of the radiator 24 and then back into the engine block by way of line 62, pump inlet 30 and the first pump 28.

The above description of embodiments of the invention is merely exemplary in nature and, thus, variations thereof are not to be regarded as a departure from the spirit and scope of the invention.

What is claimed is:

1. A method comprising flowing engine combustion exhaust through a thermoelectric device and flowing engine coolant through the thermoelectric device.

2. A system comprising an engine plumbed to flow combustion exhaust from the engine through a thermoelectric device, and the engine plumbed to flow coolant through the thermoelectric device.

3. A method comprising: starting up a combustion engine, determining whether coolant flowing through the combustion engine is above a minimum threshold, and if not, flowing engine coolant from the engine to a thermoelectric device so that heat is exchanged from exhaust gas from the engine flowing through the thermoelectric device to the coolant flowing through the thermoelectric device, and if the coolant flowing through the engine is above a minimum temperature threshold, stopping the flow of coolant from the engine to the thermoelectric device and flowing the engine coolant through a radiator to cool the coolant.

4. Another exemplary embodiment may include a method comprising starting up a combustion engine, determining whether coolant flowing through the combustion engine is above a minimum threshold, and if not, flowing engine coolant from the engine to a thermoelectric device so that heat is exchanged from exhaust gas from the engine flowing through the thermoelectric device to the coolant flowing through the thermoelectric device, and if the coolant flowing through the engine is above a minimum temperature threshold, stopping the flow of coolant from the engine to the thermoelectric device and flowing the coolant through a radiator to cool the coolant. At this time, coolant from the radiator is supplied to the thermoelectric generator for cooling.

5. Another exemplary embodiment may include a method comprising determining if an engine coolant in a vehicle is below an optimum temperature, and if so, routing the coolant from the engine to the cold side of a thermoelectric generator connected to the exhaust system of the engine to exchange heat from the exhaust gases in the exhaust system to heat the engine coolant, and thereafter returning the coolant to the engine to warm the engine.
